(19) United States
(12) Patent Application Publication
(10) Pub. No.: US 2019/0229222 A1
(43) Pub. Date: Jul. 25, 2019

(54) PHOTOVOLTAIC TEXTILE

(71) Applicant: SAINT-GOBAIN ADFORS CANADA, LTD., Grand Island, NY (US)

(72) Inventors: Donald G. Parent, Gray, ME (US); Sean L. Sweeney, Portland, ME (US); Nancy E. Brown, New Braintree, MA (US); Jackson A. Ivey, Worcester, MA (US); Sahas Rathi, Westborough, MA (US)

(21) Appl. No.: 16/253,670

(22) Filed: Jan. 22, 2019

Related U.S. Application Data
(60) Provisional application No. 62/622,108, filed on Jan. 25, 2018.

(51) Int. Cl. H01L 31/0392; B32B 5/26; B32B 5/02; H01L 31/046; H01L 27/30; H01L 51/00; H01G 9/20

(52) U.S. Cl. CPC H01L 31/03926; B32B 5/26; B32B 5/022; B32B 5/028; B32B 2457/12; H01L 27/304; H01L 51/0097; H01G 9/2086; H01G 9/2095; H01L 31/046

(57) ABSTRACT

A textile includes a flexible substrate and a photovoltaic tape adjacent to the flexible substrate. The textile may have at least one of the following properties: a power to weight ratio of at least 10 Watts per pound, a total weight to surface area of not greater than 500 grams/square-meters, and an interconnect located at an end of the photovoltaic tape. In an embodiment, the photovoltaic tape is rollable on a length of the photovoltaic tape. In an embodiment, the flexible substrate is foldable along a length contiguous to an outside edge of the photovoltaic tape.

### CROSS-REFERENCE TO RELATED APPLICATIONS

This application claims priority under 35 U.S.C. § 119(e) to U.S. Provisional Patent Application No. 62/622,108, entitled “Photovoltaic Textile,” by Donald G. Parent et al., filed Jan. 25, 2018, which is assigned to the current assignee hereof and incorporated herein by reference in its entirety.

### FIELD OF THE DISCLOSURE

The present disclosure relates to a textile including a flexible substrate and a photovoltaic tape.

### BACKGROUND

Portable solar devices typically include solar panels that are transportable to locations where sources of power are not readily available. Typical panels; however, may be heavy and difficult to transport. For instance, commercially available photovoltaic panels are multicomponent systems that add weight and complexity to the portable solar device. Further, the fabrics used with commercially available photovoltaic panels typically incorporate large quantities of individual components such as threads, fibers or tapes. For instance, electronic fabrics, such as solar fabrics, include multiple functional threads, fibers or tapes, with each usually requiring at least one pair of polarity sensitive electrical connections. Presently available solar fabric designs require time-consuming methods to make those connections. As such, commercially available portable solar devices may not provide the properties desired such as weight, handling, or transportability. Accordingly, a need continues to exist in the art for portable solar devices to meet new and sometimes demanding applications.

### SUMMARY

In an embodiment, a textile includes a flexible substrate; and a photovoltaic tape adjacent to the flexible substrate; wherein the textile has a power to weight ratio of at least about 10 Watts per pound (W/lb).

In another embodiment, a textile includes a flexible substrate; and a photovoltaic tape adjacent to the flexible substrate; wherein the photovoltaic tape is rollable on a length of the photovoltaic tape.

In yet another embodiment, a textile includes a flexible substrate; and a photovoltaic tape adjacent to the flexible substrate; wherein the flexible substrate is foldable along a length contiguous to an outside edge of the photovoltaic tape.

In yet a further embodiment, a textile includes a flexible substrate; and a photovoltaic tape adjacent to the flexible substrate; wherein the textile has a total weight to surface area of not greater than about 500 grams per square meters (g/m²).

In an embodiment, a textile includes a flexible substrate including a nonwoven scrim and a nonwoven mat overlying the nonwoven scrim; and a photovoltaic tape adjacent to the flexible substrate.

In yet another embodiment, a textile includes a flexible substrate; a photovoltaic tape adjacent to the flexible substrate; and an interconnect located at an end of the photovoltaic tape.

### BRIEF DESCRIPTION OF THE DRAWINGS

Embodiments are illustrated by way of example and are not limited in the accompanying figures.

FIG. 1 includes an exemplary flexible substrate in accordance with an embodiment described herein.

FIG. 2A includes an exemplary textile including a flexible substrate and a plurality of photovoltaic tapes in accordance with an embodiment described herein.

FIG. 2A′ includes a planar view of an exemplary photovoltaic tape.

FIG. 2B includes an electrical schematic of the textile of FIG. 2A with the photovoltaic tapes connected in series.

FIG. 2C includes an electrical schematic of the textile of FIG. 2A with the photovoltaic tapes connected in parallel.

FIG. 3A includes an electrical schematic of a textile including a flexible substrate, a plurality of voltaic tapes, and an interconnect in accordance with an embodiment described herein.

FIG. 3B. includes an exploded version of the end of photovoltaic tape and the interconnect of FIG. 3A.

FIG. 4 includes an exemplary illustration of an exemplary textile including a flexible substrate and a plurality of photovoltaic tapes in accordance with an embodiment described herein.

Skilled artisans appreciate that elements in the figures are illustrated for simplicity and clarity and have not necessarily been drawn to scale. For example, the dimensions of some of the elements in the figures may be exaggerated relative to other elements to help to improve understanding of embodiments of the invention.

### DETAILED DESCRIPTION

The following description in combination with the figures is provided to assist in understanding the teachings disclosed herein. The following discussion will focus on specific implementations and embodiments of the teachings. This focus is provided to assist in describing the teachings and should not be interpreted as a limitation on the scope or applicability of the teachings. However, other teachings can certainly be used in this application.

Before addressing details of the embodiments described below, some terms are defined or clarified. The term “filament” is intended to mean an elongated structure or fiber of any suitable length. The term “yarn” is intended to mean an ordered bundle of filaments. The term “scrim” is intended to mean a fabric that includes at least two filaments oriented in two different directions. For example, one or more filaments can be oriented in the “warp,” “main,” or “machine” direction that, in an embodiment, can be parallel to the length of the scrim. Another filament or filaments can be oriented in the “weft”, “fill”, “90”, or “cross” direction that, in an embodiment, can be parallel to the width of the scrim.

As used herein, the terms “comprises”, “comprising”, “includes”, “including”, “has”, “having” or any other variation thereof, are intended to cover a non-exclusive inclusion. For example, a method, article, or apparatus that comprises a list of features is not necessarily limited only to those features but may include other features not expressly listed or inherent to such method, article, or apparatus. Further, unless expressly stated to the contrary, “or” refers to an inclusive-or and not to an exclusive-or. For example, a condition A or B is satisfied by any one of the following: A is true (or present) and B is false (or not present), A is false (or not present) and B is true (or present), and both A and B are true (or present).

Also, the use of “a” or “an” is employed to describe elements and components described herein. This is done merely for convenience and to give a general sense of the scope of the invention. This description should be read to include one or at least one and the singular also includes the plural, or vice versa, unless it is clear that it is meant otherwise. For example, when a single item is described herein, more than one item may be used in place of a single item.

Similarly, where more than one item is described herein, a single item may be substituted for that more than one item.

Unless otherwise defined, all technical and scientific terms used herein have the same meaning as commonly understood by one of ordinary skill in the art to which this invention belongs. The materials, methods, and examples are illustrative only and not intended to be limiting. To the extent not described herein, many details regarding specific materials and processing acts are conventional and may be found in reference books and other sources within the structural arts and corresponding manufacturing arts.

In an embodiment, the present invention provides a textile including a flexible substrate and a photovoltaic tape adjacent to the flexible substrate. In a particular embodiment, the textile has a main direction and a cross direction, and the photovoltaic tape is oriented in at least one direction on the textile, for instance, in the main direction. The textile including the flexible substrate and the photovoltaic tape are configured to provide a textile that has advantageous properties such as, for instance, a textile that is lightweight, an efficient source of power, and transportable. A textile as described herein, for instance, has a power to weight ratio of at least about 10 Watts per pound. The power to weight ratio is the ratio of the power provided by the photovoltaic tape to the total weight of the textile (i.e. the total weight of the flexible substrate and photovoltaic tape). In an embodiment, the textile has a weight to surface area ratio of not greater than about 500 grams/square-meters (g/m²). The present textile provides advantageous properties not yet before achieved by commercially available textiles that incorporate standard solar panels.

Any photovoltaic tape is envisioned. Typically, the photovoltaic tape can include any photovoltaic product envisioned that absorbs and converts solar power to electricity. In an embodiment, the photovoltaic tape includes a solar organic photovoltaic (OPV) tape, an amorphous silicon (a-Si) tape, a copper indium gallium selenide (CIGS) tape, a die-sensitized solar cell (DSSC) tape, a cadmium telluride (CdTe) tape, a perovskite tape, a quantum dot tape, a crystalline silicon cell tape, the like, or any combination thereof.

In a particular embodiment, the photovoltaic tape is an organic photovoltaic (OPV) tape. An exemplary organic photovoltaic tape is described, for example, in U.S. Pat. No. 9,419,236 to Parent. In an exemplary embodiment, the organic photovoltaic tape has a configuration of at least a first electrically conducting layer, such as a positive electrode, a photovoltaic layer, and a second electrically conductive layer, such as a negative electrode, stacked in layers on a flexible film. Any order of the layers is envisioned. In a more particular embodiment, the organic photovoltaic tape has a power takeoff at a single end of the photovoltaic tape, i.e. both a positive terminal and a negative terminal at a single and same end of the photovoltaic tape. The positive and negative terminals can be contact surfaces or features. In an embodiment, the positive and negative terminals can be conductors in any reasonable form. In a particular embodiment, the positive and negative terminals may be a tape, wire, a printed circuit board, or combination thereof. In a particular embodiment, the positive and negative terminals may be presented in a consistent manner, location, position, orientation, or combination thereof to facilitate assembly. In an alternative embodiment, the photovoltaic tape has a positive terminal and a negative terminal at different ends of the photovoltaic tape.

In an embodiment, a photovoltaic tape may have any configuration envisioned. In an embodiment, the photovoltaic tape has a thickness of not greater than 0.20 mm, such as not greater than 0.15 mm. In an embodiment, the photovoltaic tape has a thickness of greater than 0.05 mm, such as greater than 0.10 mm. In an embodiment, the photovoltaic tape has a thickness of about 0.05 mm to about 0.20 mm, such as about 0.05 mm to about 0.015 mm. In an embodiment, the tape has a thickness of about 0.10 mm to about 0.20 mm, or even about 0.10 mm to about 0.015 mm. In a particular embodiment, any thickness is envisioned for the photovoltaic tape that allows flexibility of the photovoltaic tape such that the photovoltaic tape is rollable along the length of the textile. “Rollable” as used herein refers to a photovoltaic tape that can be rolled upon itself along the length of the photovoltaic tape without breakage or loss of any photovoltaic function of the photovoltaic tape in any shape envisioned. In an embodiment, the photovoltaic tape is rolled along the length around a circular core, around an oval core, around a rectangular core, or any dimensions envisioned. When “rolled”, a crease is typically not formed. For instance, the photovoltaic tape has a radius of curvature at the point of rolling of about 10 millimeters (mm), such as about 11 mm, such as about 12 mm, such as about 13 mm, such as about 14 mm, such as about 15 mm, or even greater. In an embodiment, the textile including the photovoltaic tape has a radius of curvature of about 10 mm, such as about 11 mm, such as about 12 mm, such as about 13 mm, such as about 14 mm, such as about 15 mm, or even greater. Further, the photovoltaic tape may also include a strain relief point to allow the flat photovoltaic tape to be in folded and unfolded without breakage or loss of any photovoltaic function of the tape. For instance and in an embodiment, the photovoltaic tape forms a crease at a location of the strain relief point upon the photovoltaic tape being folded.

The photovoltaic tape further has any length and width envisioned. In an embodiment, the length of the photovoltaic tape is greater than the width of the photovoltaic tape. In an embodiment, the length of the photovoltaic tape is at least about 0.5 meters, at least about 1.0 meters, at least about 5.0 meters, at least about 10.0 meters, at least about 100.0 meters, or even greater than 500.0 meters. In an embodiment, the photovoltaic tape may be made with any process for producing continuous lengths, such as a continuous process, a “roll-to-roll” process, slot-die coating, doctor blading, gravure, the like, or combination thereof. In an embodiment, the width of the photovoltaic tape is about 5 mm to about 300 mm, such as 5 mm to about 75 mm, such as about 5 mm to about 50 mm, such as about 10 mm to about 50 mm. Although described as the length being greater than the width, in an alternative embodiment, the length is the same as the width of the photovoltaic tape or the length is even less than the width of the photovoltaic tape.

The textile of the present invention includes any suitable flexible substrate, which may be configured in any reasonable orientation with the photovoltaic tape. For instance, the photovoltaic tape is adjacent to the flexible substrate and positioned in any reasonable orientation, including the photovoltaic tape overlying any suitable flexible substrate, and including any suitable flexible substrate interposed between one or more photovoltaic tapes. For instance, the flexible substrate may be continuous or discontinuous. “Continuous” as used herein refers to flexible substrate that spans across an entire width and an entire length of the textile. In an embodiment, when the flexible substrate is continuous, the photovoltaic tape overlies, and in particular, directly contacts the flexible substrate. In the alternative, “discontinuous” as used herein refers to a flexible substrate that does not span across an entire width and/or an entire length of the textile, i.e. the flexible substrate spans across only a portion of the length and the width of the textile. In an embodiment, the photovoltaic tape is configured such that the flexible substrate is positioned between adjacent photovoltaic tapes.

In an embodiment, the textile includes at least one photovoltaic tape. In an embodiment, the textile includes more than one photovoltaic tape, such as a plurality of photovoltaic tapes. In an embodiment, the plurality of photovoltaic tapes is generally in a parallel direction. In a specific embodiment, the plurality of photovoltaic tapes may have a length that is oriented generally parallel to the main direction of the textile. “Generally parallel” as used herein refers to photovoltaic tapes that are angled less than 5 degrees, such as less than 1 degree, from a desired direction, including the main direction of the textile. More specifically, the plurality of photovoltaic tapes is oriented generally parallel across a width, and in an embodiment, across any portion of the width of the textile. In an embodiment, the plurality of photovoltaic tapes is positioned across an entire width of the textile. In a particular embodiment, the photovoltaic tapes are spaced apart from each other by any suitable distance. The distance between the photovoltaic tapes is not limited and is dependent upon the final properties desired for the textile. In an embodiment, the flexible substrate is oriented at least between each outside edge of each adjacent photovoltaic tape. In an example, the flexible substrate is foldable along a length that is contiguous to the outside edge of the photovoltaic tape, i.e. the photovoltaic tape is not foldable along the length of the photovoltaic tape but rather, the flexible substrate is foldable along the length around the photovoltaic tape.

In an embodiment, any suitable flexible substrate is envisioned. “Flexible substrate” as used herein refers to a flexible substrate that is at least foldable on the cross direction, machine direction, or combination thereof. “Foldable” as used herein refers to the folding of the flexible substrate to form a crease upon being folded. A foldable flexible substrate also encompasses the ability of the flexible substrate to be rollable, i.e. the flexible substrate can be rolled upon itself in any shape envisioned without breakage or loss of strength or integrity of the flexible substrate. In an embodiment, the flexible substrate is rolled on the cross direction, machine direction, or combination thereof around a circular core, around an oval core, around a rectangular core, or any dimensions envisioned. When “rolled”, a crease is typically not formed in the flexible substrate. In an embodiment, the flexible substrate is foldable in any angle without a loss of the integrity and strength of the flexible substrate. In a particular embodiment, the flexible substrate includes an assembly of filaments. The assembly of filaments can include one or more filaments of any suitable material. In a particular embodiment, the filaments may include a polymeric material, a natural material, or combination thereof. For instance, the filaments may include a polymeric material such as a polyester, an aramid, an ultra high molecular weight polyethylene (UHMWPE) such as those available as Dyneema®, Spectra®, and MirAcle®, a poly(p-pheylene-2,6-benzobisoxazole) such as PBO Zylon®, an aromatic polyester such as Vectran®, a polyolefin such as those available from Innegra, a polyvinyl alcohol (PVA) such as those available from Teijin, a polypropylene, a polyamide, or any combination thereof. In an embodiment, the plurality of filaments can include a polyester, an aramid, a polypropylene, a polyamide, or combination thereof. In a more particular embodiment, the assembly of filaments can include a polyester. In an embodiment, the natural material includes, for example, flax, hemp, jute, cotton, the like, or combination thereof.

The flexible substrate of the present application can include any reasonable configuration. The assembly of filaments may be configured into any suitable configuration, to support the photovoltaic tape in general. For instance, the flexible substrate can be knit, woven, nonwoven, braided, stitched, and the like. In an embodiment, the flexible substrate can include any number of assemblies of filaments formed into any number of layers such as a woven scrim, a nonwoven mat, a nonwoven scrim, or combination thereof. In an embodiment, the flexible substrate includes an assembly of filaments that are knit or woven around the photovoltaic tape. In a more particular embodiment, the assembly of filaments includes yarn that is knit or woven around the photovoltaic tape alone or in conjunction with any other number of layers such as a woven scrim, a nonwoven mat, a nonwoven scrim, or combination thereof.

In an embodiment, the flexible substrate includes a nonwoven mat. In an embodiment, a “nonwoven mat” may have filaments, fibers, or swirled continuous filament that are randomly-oriented or oriented in a specified configuration. In an embodiment, the nonwoven mat includes any assembly of filaments of any reasonable length such that the nonwoven mat is flexible and provides structural integrity to the photovoltaic tape and the final textile. In an embodiment, the assembly of filaments includes chopped filaments. In a particular embodiment, the nonwoven mat includes polyester. In a preferred embodiment, the assembly of filaments is chopped to provide chopped fibers of desired lengths. The fibers are accumulated to form a layer. Any reasonable method of fixing the fibers is envisioned. For instance, a binder is applied to the fibers and cured to provide binder coated fibers. Any binder is envisioned and is discussed below.

A “woven scrim” describes a layer have warp yarns and weft yarns that are intertwined at an intersection point. The woven scrim may be formed by a conventional weaving operation, such as a loom, or a non-weaving operation. The warp yarns refer to a first set of yarns, fibers, or roving running lengthwise in long lengths and approximately parallel. The weft yarns refer to a second set of yarns, fibers, or roving that transverse the warp yarns. In a particular embodiment, the weft yarns run perpendicular to the warp and are also called fill, filling, yarn or woof.

In an embodiment, the flexible substrate includes a nonwoven scrim, such as a laid scrim. Any suitable configuration is envisioned for the laid scrim. The term “laid scrim” is intended to mean a scrim in which at least one filament overlies at least one other filament to create the scrim, i.e. the flexible substrate is nonwoven with warp yarns and weft yarns. In an exemplary embodiment, the flexible substrate includes a nonwoven laid scrim, such as a nonwoven 0/90 scrim. For example, the flexible substrate can include a first set of yarns extending generally parallel in a first direction of the nonwoven laid scrim. The flexible substrate can also include a second set of yarns extending generally parallel in a second direction of the nonwoven laid scrim that is different than the first direction of the first set of yarns and that can overlie or lie underneath the first set of yarns. The first set of yarns extend generally parallel in the main direction and the second set of yarns extend generally parallel in the cross direction.

In either a woven or nonwoven scrim configuration, the first set of yarns can include a yarn spaced apart from and generally parallel to an adjacent yarn extending in the same direction by any suitable distance. The first set of yarns also can include the same or different distances between adjacent yarns. Similarly, the second set of yarns can include a yarn spaced apart from and generally parallel to an adjacent yarn extending in the same direction by any suitable distance. The second set of yarns also can include the same or different distances between adjacent yarns. In general, any suitable spacing is envisioned between adjacent yarns, depending upon the specific tensile and weight considerations required for a flexible substrate. For example, yarns that are more closely spaced and that include a higher modulus and denier can create a stronger flexible substrate. Yarn spacing can also be affected by the particular yarn material or materials used to meet an industrial specification. Moreover, the flexible substrate can include a variety of layers, each of which can include different spacing between the yarns or filaments, and different yarn or filamentary materials.

In an exemplary embodiment, the flexible substrate can include a mix or blend of more than one yarn in at least one of the directions of the woven scrim or nonwoven scrim. For example, a flexible substrate can be made with a combination of polyester and aramid yarns. In an example, every fourth yarn in the second, or cross, direction can be an aramid yarn to increase the fill strength (e.g., the tensile strength in the cross or fill direction) of a scrim, including an increase in fill strength of at least 25%.

The assembly of filaments can include a monofilament or it can include a number of filaments per assembly, such as greater than 50 filaments, greater than 100 filaments, greater than 200 filaments, greater than 500 filaments, or greater than 1,000 filaments. Typically, the assembly includes less than 300,000 filaments per assembly, such as less than 200,000 filaments or less than 100,000 filaments. A typical range can be 1,000 to 60,000 filaments per assembly.

Each of the assemblies of filaments can include various configurations of filaments within each assembly. The assembly of filaments depends upon the final configuration desired for the individual layer of the flexible substrate and the final textile. In an embodiment, the assembly of filaments can include a flattened, substantially untwisted ribbon-like configuration of organic filaments, inorganic filaments, or combination thereof, such as a tow or a tape. By “substantially untwisted,” it is meant that the assembly of filaments can include less than 0.5 twists per centimeter, such as less than 0.4, less than 0.25, or even less than 0.1 twists per centimeter. In another embodiment, the assembly of filaments can be configured to include an ordered or unordered bundle of filaments. For example, the assembly of filaments can be configured as an unordered bundle of filaments, such as a roving, or as an ordered bundle of filaments, such as a yarn with one or more plies. In both instances of a roving and a yarn, the configuration of the filaments may include any reasonable amount of twist applied to the filaments or bundle.

The configuration of each of the assemblies of filaments can include various dimensions. For example, the assembly of filaments can include a cross-section that has an aspect ratio defined as a ratio of the width of the assembly of filaments to the height of the assembly of filaments. In an embodiment, the assembly of filaments can include an aspect ratio value less than 50:1, such as 10:1 for an assembly of filaments that includes 12,000 filaments. In another embodiment, the assembly of filaments can include an aspect ratio value greater than 2:1, such as 3:1, such as 5:1, or such as 7:1, or such as 10:1. Each assembly of filaments can have the same or different materials, number of filaments, configurations, aspect ratios, and the like depending on the properties desired for the flexible substrate and ultimately, the final textile.

Although the laid scrim is generally described as a 0/90 scrim, any direction of the first set of yarns and the second set of yarns is envisioned. For instance, the flexible substrate may include an angled scrim. In a particular embodiment, the angled scrim is a nonwoven laid scrim or a woven scrim. The angled scrim can include at least one assembly of filaments, such as at least one first assembly of filaments, oriented at any suitable angle. For instance, any suitable angle may be an off-angle measured relative to the cross direction of the flexible substrate. In an embodiment, the assembly of filaments can be oriented at an off-angle between 5 degrees and 85 degrees, such as between 15 degrees and 85 degrees, or such as between 20 degrees and 80 degrees relative to the cross direction of the flexible substrate. Any suitable off-angle is envisioned. Within the angled scrim, it is envisioned that the assembly of filaments can be oriented at a suitable off-angle and also can be oriented at a positive value, a negative value, or a combination thereof, of that off-angle. Any suitable positive or negative value of that off-angle is envisioned.

The assembly of filaments in any configuration may be stabilized and fixed using various approaches. In an embodiment, any one of the woven scrim, the nonwoven mat, the nonwoven scrim, or combination thereof can include a binder to provide a bond between the assemblies of filaments within a layer. For instance, the binder may be on any portion of the assembly of filaments to provide a bond between adjacent surfaces of the filaments. In an example, the binder may provide a bond between the assembly of filaments, such as bonding the assembly of filaments within a nonwoven mat, a nonwoven scrim, a woven scrim, and the like. Further, a binder may provide a bond between adjacent layers such as between a nonwoven mat, a nonwoven scrim, a woven scrim, and the like.

In an embodiment, any suitable binder may be envisioned that provides a bond to an assembly of filaments or an adjacent layer. In a particular embodiment, the binder can include an adhesive binder, such as a thermoplastic adhesive binder, a thermosetting adhesive binder, or any combination thereof. If desired, the binder can be non-tacky at room temperature. One advantage to the use of an adhesive binder when applied to the assembly of filaments is its ability to increase the shear strength of the final textile. A second advantage is that an adhesive binder may provide less bulk or weight to the flexible substrate than stitching. Yet another advantage is that an adhesive binder can be applied to one or more adjacent surfaces of the filaments and/or the layers of the flexible substrate during its production at a much faster rate than another means of stabilizing or fixing adjacent surfaces of the filaments and/or the layers of the flexible substrate (e.g., stitching) during its production. A still further advantage to using an adhesive binder is the stability that the adhesive binder affords to the flexible substrate.

The same or different binder may be used to provide the bond between assemblies of adjacent filaments and/or adjacent layers. In an embodiment, the bond may be activated under conditions such as heat, pressure, or a combination thereof. During manufacturing, the flexible substrate may be heated to allow the binder to secure the layers of the flexible substrate to one another and to fix the assembly of filaments within the flexible substrate, any and all of each layer to enhance the stability, durability, and strength of the flexible substrate.

In an embodiment, the flexible substrate uses stitching to secure the layers, whether the layer includes assemblies of filaments for a nonwoven mat, a woven scrim, a nonwoven scrim, or combination thereof. In a further embodiment, the flexible substrate includes a film to secure any of the layers.

In a particular embodiment, the flexible substrate is configured such that it is foldable in any direction. For instance, the flexible substrate is foldable on a cross direction, a machine direction, or combination thereof. In a particular embodiment, the flexible substrate has a desirable thickness. For instance, the thickness is dependent upon the final properties desired for the textile. In an embodiment, the total thickness of the flexible substrate is at least about 0.025 mm, such as at least about 0.05 mm, such as at least about 0.1 mm, such as at least about 0.1 mm to about 2.0 mm. If multiple layers are used for the flexible substrate, each layer can have any thickness envisioned with the proviso that the thickness of the multiple layers is not greater than the total thickness of the flexible substrate.

Any number of assemblies of filaments and any number of layers for the flexible substrate may be envisioned in light of industrial considerations such as the overall areal weight of the final textile. For instance, any number of flexible substrates, i.e. assemblies of filaments, may be envisioned such that the photovoltaic tape is sandwiched between at least two flexible substrates. In an embodiment, the flexible substrate can include any optional layers such as a uni-directional fabric, an angled scrim, a film, a foam, or any combination thereof. The optional layers may be continuous or discontinuous and may be located in any desirable position. In an embodiment, an optional layer may be within the flexible substrate or adjacent to a portion of the flexible substrate. For instance, a foam can be adjacent to and in direct contact with an edge of a portion of the flexible substrate wherein the foam can be folded into the flexible substrate and the photovoltaic tape and flexible substrate can be wrapped around the foam.

Any method of fastening the photovoltaic tape to the flexible substrate is envisioned. For instance, the photovoltaic tape is laminated, knit, stitched, adhered via an adhesive, or combination thereof to directly contact the flexible substrate. The method of fastening the photovoltaic tape to the flexible substrate depends on the final textile product desired. In an embodiment, the flexible substrate uses knitting, stitching, or weaving to secure the photovoltaic tape and form the textile. In a particular embodiment, the flexible substrate is an assembly of filaments, such as yarns woven around a plurality of photovoltaic tapes to fasten the photovoltaic tapes together. In a particular embodiment, the photovoltaic tape may be configured with slots, slits, holes, or combination thereof to weave, knit, or stitch the flexible substrate to the photovoltaic tape. When laminated, any reasonable method of laminating the photovoltaic tape to the flexible substrate is envisioned. When the photovoltaic tape is adhered to the flexible substrate via an adhesive, any reasonable adhesive is envisioned and includes, for example, a thermoplastic adhesive, a thermoset adhesive, or combination thereof.

In a particular embodiment, the flexible substrate and photovoltaic tape provides a textile that is both light with an effective power source. For instance, the textile has a power to weight ratio of at least about 10 Watts per pound (W/lb), such as at least about 30 W/lb, such as at least about 50 W/lb, or even at least 100 W/lb. Further, the textile has a total weight to surface area of not greater than about 500 grams/square-meters (g/m²), such as about 300 grams/square-meters to about 500 grams/square-meters. Any size of the textile is envisioned and is only limited by voltage and weight considerations.

The textile may further include an interconnect where electrical connections may be provided at an end of the photovoltaic tape and between a plurality of photovoltaic tapes. In particular, the interconnect is a conductive mechanism to transport power from the photovoltaic tape. The interconnect of the present invention may provide a connection to a singular photovoltaic tape as well as a connection across a plurality of photovoltaic tapes with a positive terminal port and a negative terminal port at a terminal end of the interconnect. The terminal end of the interconnect may include any type of port for electrical termination. The interconnect includes any electrical connection envisioned. For instance, the electrical connection may be provided as an integral portion or a separate portion from the textile. In an embodiment, an electrical connection of the interconnect to the photovoltaic tape and between a plurality of photovoltaic tapes may be made via compression, conductive tape, or a combination thereof. In an example, the electrical connection of the interconnect is via compression contact to a conductive material, such as a conductive foil, such as copper foil, or soldering. The conductive tape includes, for example, a conductive adhesive, a foil, an expanded metal, a wire braid, a stranded wire, or combination thereof. In a particular embodiment, the electrical connection is made without any discrete wired connections. In an embodiment, the electrical connections may use flex-circuit devices, such as a printed circuit board, alone or in combination with a compression contact, a conductive tape, or combination thereof. In an embodiment, the electrical connections are in series, parallel, or any combination thereof, as desired by the final textile and product specification.

In a particular embodiment, the photovoltaic tape advantageously may include both a negative polarity and a positive polarity to exit the photovoltaic tape at a single end. In this embodiment, the interconnect is provided at the single end, providing for simplicity of design, ease of assembly, and ease of drawing power from the final textile. In an alternative embodiment, the photovoltaic tape includes a negative polarity and a positive polarity to exit the photovoltaic tape at different ends, such as opposite ends of the photovoltaic tape.

Any further component may be integrated with the textile and includes any reasonable component for a photovoltaic system. Additional components include, but are not limited to a mounting system, a storage system, any cabling, an electrical accessory, a power converter, an energy storage device such as an integrated battery, a diode, or any combination thereof. In an example, a diode, such as a bypass diode, may be integrated between the negative terminal and the positive terminal of the photovoltaic tape. Any number of diodes may be envisioned.

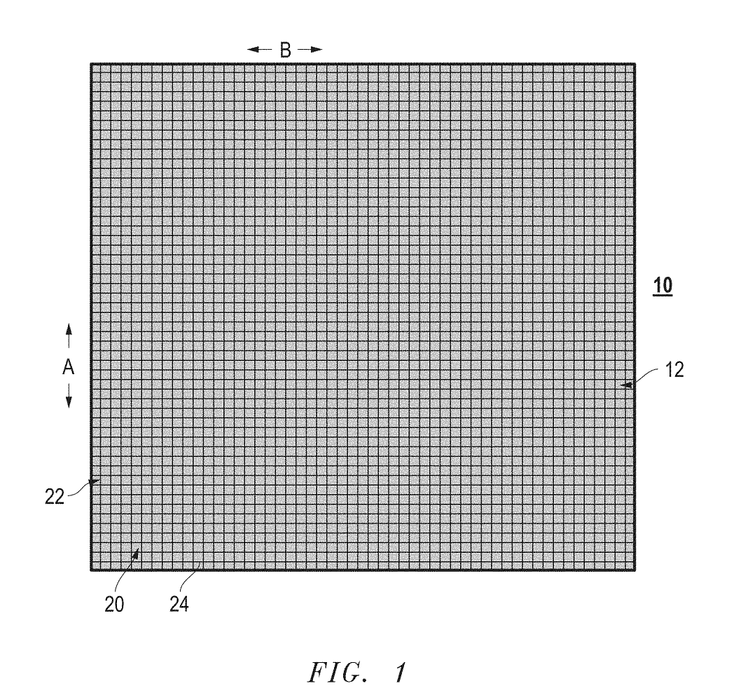

Turning to FIG. 1, an exemplary flexible substrate is shown. The flexible substrate 10 includes a nonwoven mat 12. The nonwoven mat 12 generally includes a plurality of filaments that are typically randomly-oriented and adhered by a binder (not shown). The nonwoven mat 12 directly contacts laid scrim 20 and is adhered thereto by a binder (not shown). The laid scrim 20 as illustrated includes a nonwoven laid scrim and, more particularly, a 0/90 scrim. At least one yarn 22 from laid scrim 20 can extend generally parallel to direction A of nonwoven laid scrim 20 which, in an embodiment, can include the main direction of nonwoven laid scrim 20. At least one yarn 24 from laid scrim 20 can extend generally parallel to direction B of nonwoven laid scrim 20 which, in an embodiment, can include the cross direction of nonwoven laid scrim 20 and which can be perpendicular to direction A. Filaments for the nonwoven mat 12 and yarns 22 and 24 can include any suitable materials as described above and include any suitable configuration. In an embodiment, nonwoven mat 12 and nonwoven laid scrim 20 can include filaments and/or yarns that all include the same material such as polyester, or can include yarns that include different materials, such as alternating polyester yarns with aramid yarns. Although not illustrated, the flexible substrate can include the optional uni-directional fabric, an angled scrim, a film, a foam, or any combination thereof.

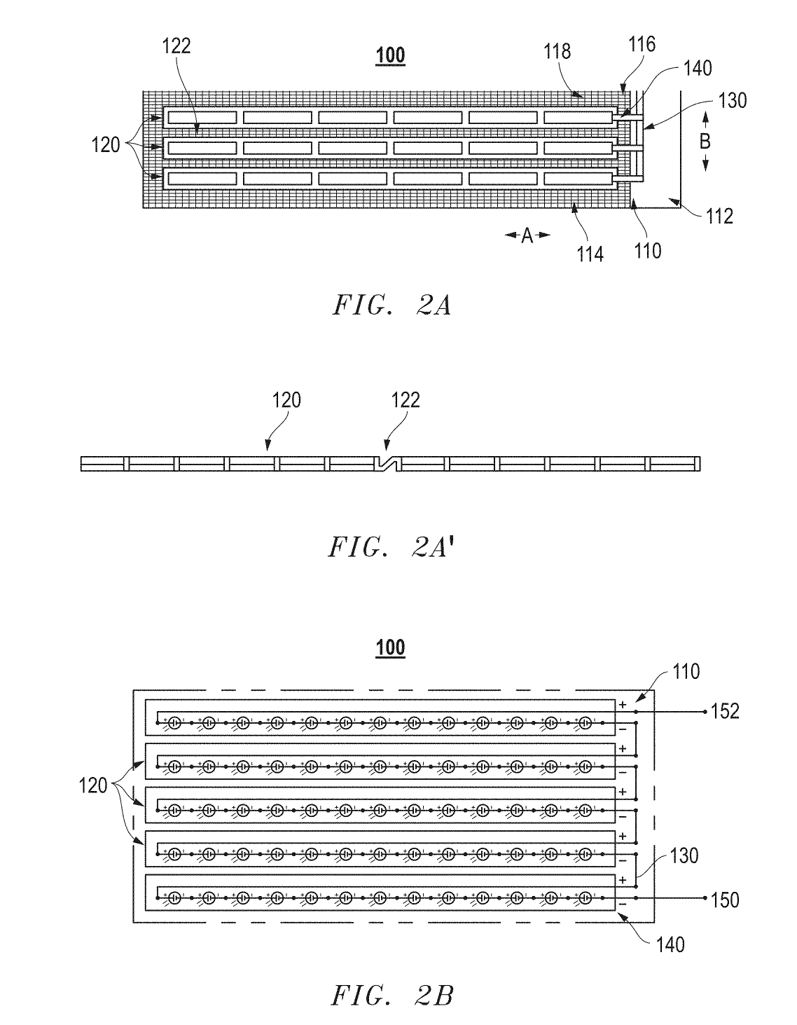

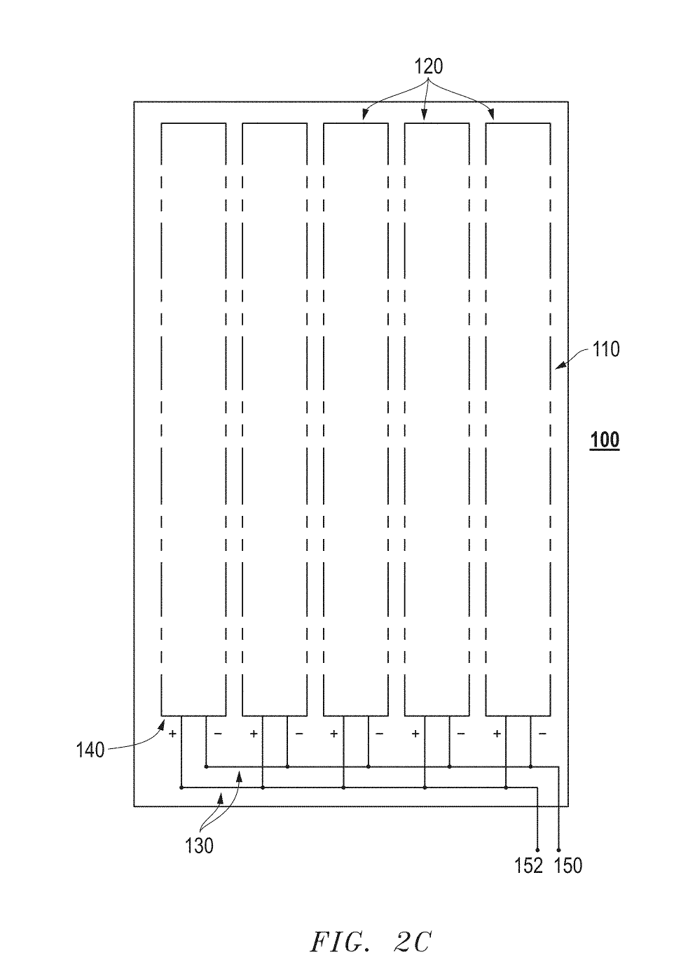

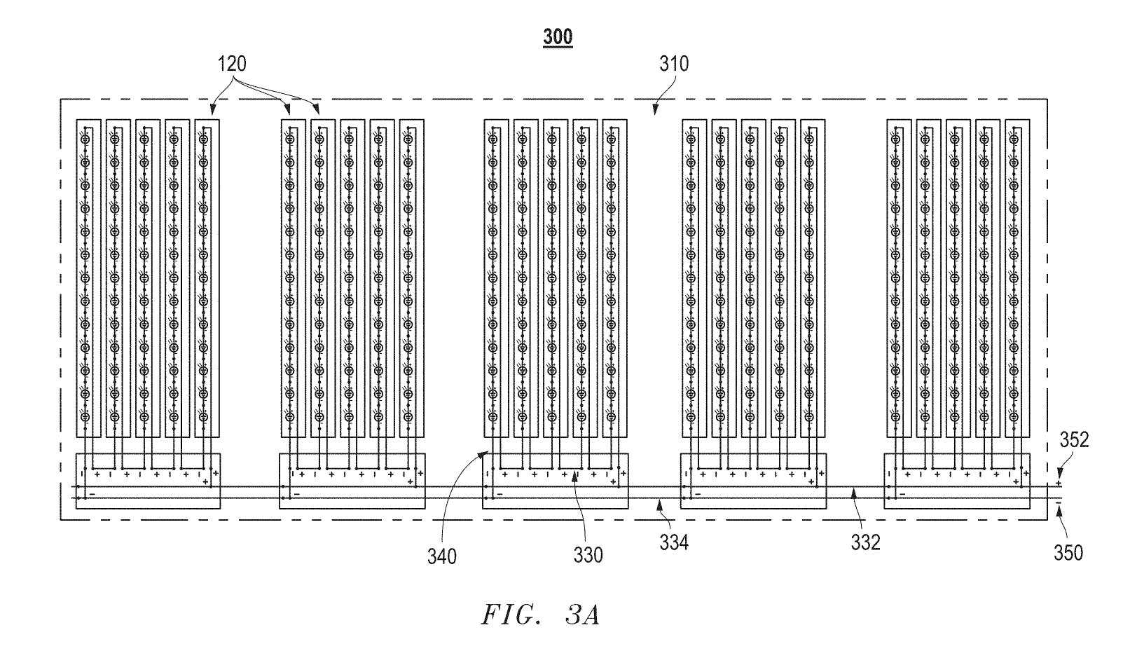

Turning to FIG. 2A, an exemplary textile 100 including a flexible substrate 110 and a plurality of photovoltaic tapes 120 is shown from a perspective view. The textile 100 includes the flexible substrate of FIG. 1 including a nonwoven mat 112 and a nonwoven laid scrim 114 that includes at least one yarn 116 from nonwoven laid scrim 114 that can extend generally parallel to direction A of nonwoven laid scrim 114 which, in an embodiment, can include the main direction of nonwoven laid scrim 114. At least one yarn 118 from nonwoven laid scrim 114 can extend generally parallel to direction B of nonwoven laid scrim 114 which, in an embodiment, can include the cross direction of nonwoven laid scrim 114 and which can be perpendicular to direction A. The nonwoven mat 112 directly contacts nonwoven laid scrim 114 and is adhered thereto by a binder (not shown). Each photovoltaic tape 120 is oriented in the main direction, i.e. parallel to direction A, of the flexible substrate 110. Any number of photovoltaic tapes 120 can be included and is only limited to the size and/or voltage desired for the final textile 100. Further included is an interconnect 130 which provides a mechanism to draw power from a singular end of the photovoltaic tape 140 and which provides an electrical connection between the photovoltaic tapes 120.

The photovoltaic tape 120 may be directly in contact with the flexible substrate 110 by any reasonable means. For instance, as illustrated, the photovoltaic tape 120 is laminated to the flexible substrate 110. However, the photovoltaic tape 120 may be knit, stitched, adhered via an adhesive, or combination thereof to directly contact the flexible substrate 110.

Although shown in a flat configuration, the textile 100 and photovoltaic tape 120 are rollable in the A direction. In an embodiment, depending on the dimensions of the photovoltaic tape, the textile 100 and photovoltaic tape 120 may also be rollable in the B direction. Although not illustrated in FIG. 2A, if a gap is created between the photovoltaic tapes 120 in the A direction, there can be a fold in the textile 100 at the gap. A photovoltaic tape 120 can be seen in FIG. 2A′ that shows a stress relief point 122 along the length of the photovoltaic tape 120. If the photovoltaic tape 120 includes a stress relief point 122, such as at a location along the length and across the width of the photovoltaic tape 120, there can be a fold in the textile 100 and the photovoltaic tape 120 at the stress relief point 122. Although not illustrated, a stress relief point 122 may be along the width and down the length of the photovoltaic tape 120. Further, the textile 100 can be folded along the B direction, with a crease of the fold located along the length of the photovoltaic tape 120 in a space contiguous to an outside edge 122 of the photovoltaic tape 120, such as the space between the photovoltaic tapes 120.

Turning to FIG. 2B, an electrical schematic view of textile 100 from FIG. 2A is illustrated with the photovoltaic tapes 120 connected in series. Textile 100 includes a flexible substrate 110 and a plurality of photovoltaic tapes 120 is shown. As seen in FIG. 2B, each photovoltaic tape 120 has a positive and negative terminal at a singular end 140 of the textile 100. Between each photovoltaic tape 120 includes an interconnect 130 which provides a negative to positive connection between each of the photovoltaic tapes 120 in series. Further included are an electrical termination point with a negative terminal port 150 and a positive terminal port 152.

Turning to FIG. 2C, an electrical schematic view of textile 100 from FIG. 2A is illustrated with the photovoltaic tapes 120 connected in parallel. Textile 100 includes a flexible substrate 110 and a plurality of photovoltaic tapes 120 is shown. As seen in FIG. 2C, each photovoltaic tape 120 has a positive and negative terminal at a singular end 140 of the textile 100. Between each photovoltaic tape 120 includes an interconnect 130 which provides a positive to positive connection and a negative to negative connection between each of the photovoltaic tapes 120 in parallel. Further included are an electrical termination point with a negative terminal port 150 and a positive terminal port 152.

Although FIGS. 2B and 2C illustrate separate schematics for photovoltaic tapes in either a parallel connection or a series connection, any circuitry is envisioned and includes a combination of parallel and series connections. In an embodiment, the photovoltaic tapes are arranged in series and then subsequently connected together in parallel.

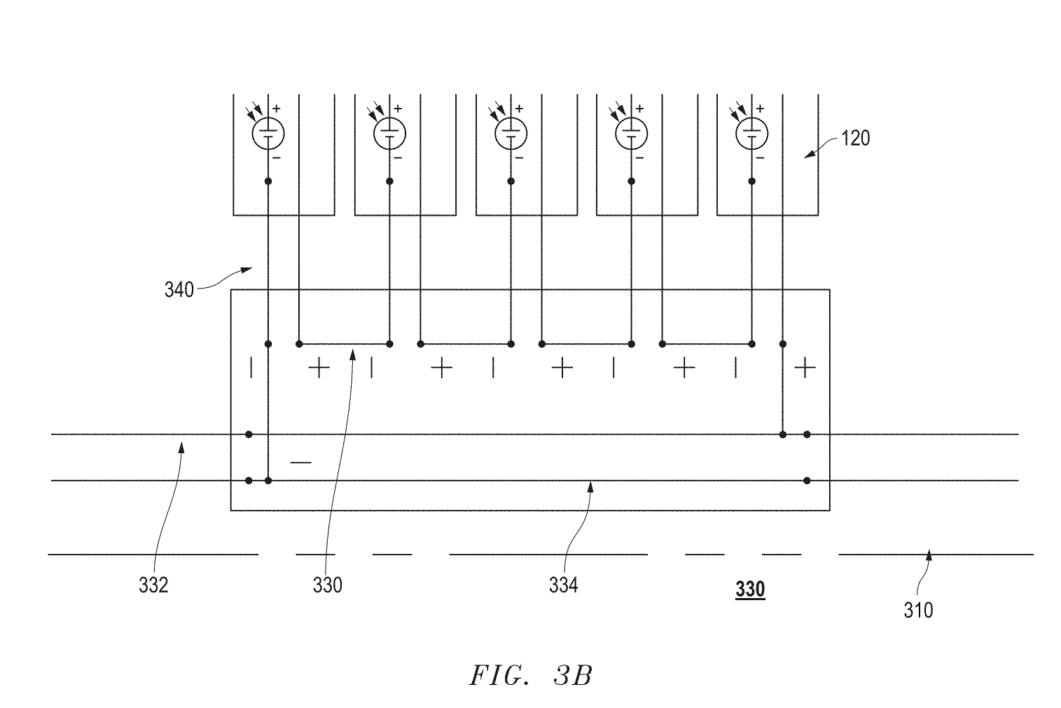

Turning to FIG. 3A, an electrical schematic view of a textile 300 is illustrated with the photovoltaic tapes 120 connected in series. Textile 300 includes a flexible substrate 310 and a plurality of photovoltaic tapes 120 is shown. As seen in FIG. 3A, each photovoltaic tape 120 has a positive and negative terminal at a singular end 340 of the textile 300. Between each photovoltaic tape 120 includes an interconnect 330 which provides a negative to positive connection between each of the photovoltaic tapes 120 in series. The interconnect 330 includes a first busbar 332 that provides a connection between the positive terminal of the photovoltaic tapes 120 and a second busbar 334 that provides a connection between the negative terminal of the photovoltaic tapes 120. Any configuration or combination of materials is envisioned for any portion of the interconnect 330, the first busbar 332, and the second busbar 334. For instance, the interconnect 330 includes a printed circuit board for the singular end 340, the first busbar 332, the second busbar 334, or combination thereof alone or in combination with a conductive adhesive, a foil, an expanded metal, a wire braid, a stranded wire, or combination thereof. Further included are an electrical termination point with a negative terminal port 350 and a positive terminal port 352. FIG. 3B is an exploded view of the end of the photovoltaic tape 120 and interconnect 330.

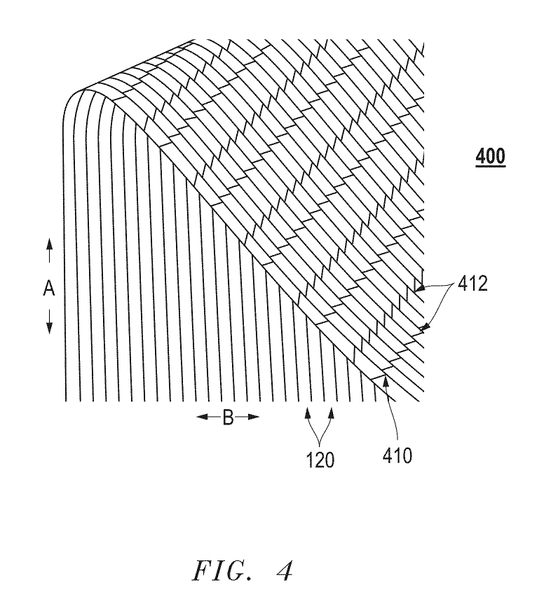

Turning to FIG. 4, an illustrative and exemplary textile 400 is included. For instance, a plurality of photovoltaic tapes 120 are illustrated with a flexible substrate 410. In this embodiment, the flexible substrate 410 includes an assembly of filaments 412, illustrated as a yarn, where the yarn is woven around the photovoltaic tape 120. As seen in FIG. 4, the textile 400 and photovoltaic tapes 120 can be rolled in the A direction. Further, the textile 400 can be folded along the B direction, with a crease of the fold located in a space between the photovoltaic tapes 120.

A textile as described herein can be used to meet new and sometimes demanding applications in both the public and private sector. For example, the textile described can be used in military applications for fabrics that are ultra-light, highly resistant to tearing, and easily transportable. The textile could be equally useful in commercial or private settings, such as in use in high performance camping gear and fabrics designed to protect against natural elements. More generally, the textile as described herein has applicability in a range of industrial fields where a solar power is desired. In an exemplary embodiment, the textile has a configuration of a tent, a tarp, an awning, an automobile cover, a temporary building structure, a shade, or a fly.

Many different aspects and embodiments are possible. Some of those aspects and embodiments are described herein. After reading this specification, skilled artisans will appreciate that those aspects and embodiments are only illustrative and do not limit the scope of the present invention. Embodiments may be in accordance with any one or more of the embodiments as listed below.

Embodiment 1. A textile including a flexible substrate; and a photovoltaic tape adjacent to the flexible substrate; wherein the textile has a power to weight ratio of at least 10 Watts per pound (W/lb).

Embodiment 2. A textile including a flexible substrate; and a photovoltaic tape adjacent to the flexible substrate; wherein the photovoltaic tape is rollable on a length of the photovoltaic tape.

Embodiment 3. A textile including a flexible substrate; and a photovoltaic tape adjacent to the flexible substrate; wherein the flexible substrate is foldable along a length contiguous to an outside edge of the photovoltaic tape.

Embodiment 4. A textile including a flexible substrate; and a photovoltaic tape adjacent to the flexible substrate; wherein the textile has a total weight to surface area of not greater than about 500 grams/square-meters (g/m²).

Embodiment 5. A textile including a flexible substrate including a nonwoven scrim and a nonwoven mat directly in contact with the nonwoven scrim; and a photovoltaic tape adjacent to the flexible substrate,

Embodiment 6. A textile including a flexible substrate; a photovoltaic tape directly in contact with the flexible substrate; and an interconnect located at an end of the photovoltaic tape.

Embodiment 7. The textile of any one of the preceding embodiments, wherein the photovoltaic tape includes a solar organic photovoltaic (OPV) tape, an a-Si tape, or a CIGS tape.

Embodiment 8. The textile of embodiment 7, wherein the photovoltaic tape includes a solar organic photovoltaic (OPV) tape.

Embodiment 9. The textile of any one of the preceding embodiments, wherein the photovoltaic tape has a continuous length of at least about 0.5 meters, at least about 5.0 meter, at least about 10.0 meters, at least about 100.0 meters, or even at least about 500.0 meters.

Embodiment 10. The textile of any one of the preceding embodiments, wherein the photovoltaic tape has a thickness of not greater than 0.2 mm, such as not greater than 0.15 mm.

Embodiment 11. The textile of any one of the preceding embodiments, wherein the textile has a power to weight ratio of at least 30 W/lb, such as at least 50 W/lb, or at least 100 W/lb.

Embodiment 12. The textile of any one of the preceding embodiments, wherein the photovoltaic tape is laminated, knit, stitched, adhered via an adhesive, or combination thereof to directly contact the flexible substrate.

Embodiment 13. The textile of any one of the preceding embodiments, wherein flexible substrate has a thickness of 0.025 mm to about 2.00 mm.

Embodiment 14. The textile of any one of embodiments 1 or 3-13, wherein the textile is rollable on a length of the photovoltaic tape.

Embodiment 15. The textile of any one of embodiments 1, 2 or 4-14, wherein the textile is foldable along a length contiguous to an outside edge of the photovoltaic tape.

Embodiment 16. The textile of any one of the preceding embodiments, wherein the flexible substrate is foldable on a cross direction, a machine direction, or combination thereof.

Embodiment 17. The textile of any one of the preceding embodiments, wherein the flexible substrate includes an assembly of filaments.

Embodiment 18. The textile of embodiment 17, wherein the assembly of filaments includes a polymer fiber, a natural fiber, or combination thereof.

Embodiment 19. The textile of embodiment 18, wherein the polymer fiber includes a polyester, an aramid, a polypropylene, a polyamide, or combination thereof.

Embodiment 20. The textile of any one of embodiments 17-19, wherein the assembly of filaments includes a woven scrim, a nonwoven mat, a nonwoven scrim, or combination thereof.

Embodiment 21. The textile of embodiment 20, wherein the nonwoven scrim includes a 0/90 scrim, and wherein the 0/90 scrim includes: a first set of yarns extending generally parallel to the main direction; and a second set of yarns extending generally parallel to the cross direction and generally perpendicular to the main direction.

Embodiment 22. The textile of any one of embodiments 20-21, wherein the flexible substrate includes a nonwoven mat directly in contact with a nonwoven scrim.

Embodiment 23. The textile of embodiment 22, wherein the flexible substrate comprises a binder to provide a bond between the nonwoven mat and the nonwoven scrim.

Embodiment 24. The textile of any one of embodiments 1-5 and 7-23, further including an interconnect located at an end of the photovoltaic tape.

Embodiment 25. The textile of any one of the preceding embodiments, wherein the interconnect provides a connection between a plurality of photovoltaic tapes.

Embodiment 26. The textile of any one of the preceding embodiments, further including a foam.

Embodiment 27. The textile of any one of the preceding embodiments, wherein the textile is configured for a tent, a tarp, an awning, an automobile cover, a temporary building structure, a shade, or a fly.

Embodiment 28. The textile of any one of the preceding embodiments, wherein the textile has a total weight to surface area of about 300 grams/square-meters to about 500 grams/square-meters.

Certain features, for clarity, described herein in the context of separate embodiments, may also be provided in combination in a single embodiment. Conversely, various features that are, for brevity, described in the context of a single embodiment, may also be provided separately or in any subcombination. Further, reference to values stated in ranges includes each and every value within that range.

Benefits, other advantages, and solutions to problems have been described above with regard to specific embodiments. However, the benefits, advantages, solutions to problems, and any feature(s) that may cause any benefit, advantage, or solution to occur or become more pronounced are not to be construed as a critical, required, or essential feature of any or all the claims.

The specification and illustrations of the embodiments described herein are intended to provide a general understanding of the structure of the various embodiments. The specification and illustrations are not intended to serve as an exhaustive and comprehensive description of all of the elements and features of apparatus and systems that use the structures or methods described herein. Separate embodiments may also be provided in combination in a single embodiment, and conversely, various features that are, for brevity, described in the context of a single embodiment, may also be provided separately or in any subcombination. Further, reference to values stated in ranges includes each and every value within that range. Many other embodiments may be apparent to skilled artisans only after reading this specification. Other embodiments may be used and derived from the disclosure, such that a structural substitution, logical substitution, or another change may be made without departing from the scope of the disclosure. Accordingly, the disclosure is to be regarded as illustrative rather than restrictive.

What is claimed is:

1. A textile comprising:
a flexible substrate; and
a photovoltaic tape adjacent to the flexible substrate; wherein the textile has a power to weight ratio of at least 10 Watts per pound (W/lb).

2. The textile of claim 1, wherein the photovoltaic tape comprises a solar organic photovoltaic (OPV) tape, an a-Si tape, or a CIGS tape.

3. The textile of claim 1, wherein the photovoltaic tape has a continuous length of at least about 0.5 meters, at least about 5.0 meter, at least about 10.0 meters, at least about 100.0 meters, or even at least about 500.0 meters.

4. The textile of claim 1, wherein the photovoltaic tape has a thickness of not greater than 0.2 mm, such as not greater than 0.15 mm.

5. The textile of claim 1, wherein the textile has a power to weight ratio of at least 30 W/lb, such as at least 50 W/lb, or at least 100 W/lb.

6. The textile of claim 1, wherein the photovoltaic tape is laminated, knit, stitched, adhered via an adhesive, or combination thereof to directly contact the flexible substrate.

7. The textile of claim 1, wherein flexible substrate has a thickness of 0.025 mm to about 2.00 mm.

8. The textile of claim 1, wherein the textile is rollable on a length of the photovoltaic tape.

9. The textile of claim 1, wherein the textile is foldable along a length contiguous to an outside edge of the photovoltaic tape.

10. The textile of claim 1, wherein the flexible substrate is foldable on a cross direction, a machine direction, or combination thereof.

11. The textile of claim 1, wherein the flexible substrate comprises an assembly of filaments.

12. The textile of claim 11, wherein the assembly of filaments comprises a polymer fiber, a natural fiber, or combination thereof.

13. The textile of claim 11, wherein the assembly of filaments comprises a woven scrim, a nonwoven mat, a nonwoven scrim, or combination thereof.

14. The textile of claim 13, wherein the nonwoven scrim comprises a 0/90 scrim, and wherein the 0/90 scrim comprises:
a first set of yarns extending generally parallel to the main direction; and
a second set of yarns extending generally parallel to the cross direction and generally perpendicular to the main direction.

15. The textile of claim 13, wherein the flexible substrate comprises a nonwoven mat directly in contact with a nonwoven scrim.

16. The textile of claim 1, further comprising an interconnect located at an end of the photovoltaic tape.

17. The textile of claim 1, further comprising a foam.

18. The textile of claim 1, wherein the textile has a total weight to surface area of about 300 grams/square-meters to about 500 grams/square-meters.

19. A textile comprising:
a flexible substrate comprising a nonwoven scrim and a nonwoven mat directly in contact with the nonwoven scrim; and
a photovoltaic tape adjacent to the flexible substrate,

20. A textile comprising:
a flexible substrate;
a photovoltaic tape directly in contact with the flexible substrate; and
an interconnect located at an end of the photovoltaic tape.
